(19) United States
(12) Patent Application Publication
(10) Pub. No.: US 2006/0191482 A1
(43) Pub. Date: Aug. 31, 2006

(54) Apparatus and method for processing wafer

(76) Inventors: Seiichiro Kanno, Tokyo (JP); Junichi Tanaka, Tokyo (JP); Go Miya, Tokyo (JP); Tsunehiko Tsubone, Hikari-shi (JP); Akitaka Makino, Hikari-shi (JP); Toshio Masuda, Tokyo (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/074,717

(22) Filed: Mar. 9, 2005

(30) Foreign Application Priority Data
Feb. 4, 2005 (JP) 2005-028804

(51) Int. Cl. C23C 16/00

(52) U.S. Cl. 118/725; 219/444.1

(57) ABSTRACT

A wafer processing apparatus capable of obtaining a uniform CD distribution within a wafer is provided. The wafer processing apparatus comprises at least two separate circuits of temperature regulating means provided in a wafer stage, a plurality of cooling gas pressure regulating means for feeding cooling gas between the semiconductor wafer and the wafer stage, means for regulating heater input power, and a control computer. The control computer receives input of line width dimensions resulting from processes in an arbitrary plurality of temperature conditions obtained by changing at least one of the conditions of the temperature of the temperature regulating agent, the cooling gas pressure, and the input power of the heater. The line width dimensions are used to calculate, and control, at least one of the temperature of the temperature regulating agent, the cooling gas pressure, and the input power of the heater for obtaining an arbitrary etching line width dimension.

The present application is based on and claims priority of Japanese patent application No. 2005-028804 filed on Feb. 4, 2005, the entire contents of which are hereby incorporated by reference.

### BACKGROUND OF THE INVENTION

1. Field of the Invention

The invention relates to an etching technique for a semiconductor wafer, and more particularly to a wafer processing apparatus and a wafer processing method with reduced dimensional variation within a semiconductor wafer.

2. Description of the Related Art

In recent years, circuit patterns processed on a semiconductor wafer continue to shrink with the trend toward higher integration of semiconductor devices, which requires increasingly higher accuracy of processing dimension. In this situation, temperature control of a semiconductor wafer during processing is a problem of vital importance.

For example, when a semiconductor wafer is etched with plasma, typically, a bias voltage is applied to the semiconductor wafer to cause an electric field to accelerate ions and attract them to the semiconductor wafer, thereby achieving anisotropic features. At this time, the semiconductor wafer involves heat input, which increases its temperature.

The increased wafer temperature affects the etching result. For example, in etching polysilicon to be used for electrodes of a semiconductor device, the ultimately obtained line width is significantly affected by redeposition of reaction products deposited on the sidewall during etching. On the other hand, the deposition rate of reaction products depends on wafer temperature. Hence the etching result will have poor reproducibility without temperature control of the wafer during processing. Moreover, the distribution of reaction products tends to have a lower density near the periphery than near the center of the wafer. If the temperature is the same, the line width is likely to be small near the periphery as a result of less redeposition. Therefore, the temperature distribution within a wafer must be actively controlled in order to obtain a uniform line width (CD) within a wafer.

In addition, the density distribution of reaction products on a semiconductor wafer also depends on the etching condition. When the etching condition changes during a single process such as, for example, in sequential processing for antireflective coating and polysilicon, the temperature distribution for achieving a uniform CD distribution within a wafer changes with the condition.

Conventionally, however, the temperature distribution of a semiconductor wafer achieving the most uniform CD distribution within a wafer cannot be easily obtained. As a result, the temperature of coolant, the pressure of cooling gas, and the heater power are empirically determined for processing. There is no control for regulating the within-wafer temperature distribution in response to the change of etching condition.

In a method of sequentially etching different materials proposed in the conventional art, during the first step of processing a semiconductor wafer, the temperature is gradually changed to a temperature required for the next step, thereby avoiding degradation of throughput due to temperature switching time. In an example method, the cooling rate of cooling means and the heating rate of heater output are regulated (see, for example, Japanese Laid-Open Patent Application 10-144655 (1998)).

A problem in the above-described conventional art is the difficulty of etching with the temperature distribution that results in the smallest within-wafer dimensional variation after etching. This is because no consideration is given to regulating the within-wafer temperature distribution. Another problem is that, under step-by-step changing etching conditions, such as in sequential processing for different kinds of films, a temperature distribution capable of reducing dimensional variation cannot be used for each particular etching condition, which makes it difficult to achieve a uniform etching result.

### SUMMARY OF THE INVENTION

A first object of the invention is to provide a wafer processing apparatus and a wafer processing method with reduced within-wafer dimensional variation in which an etching condition achieving a within-wafer temperature distribution with small dimensional variation is determined from within-wafer dimensional data obtained in different temperature conditions, and the etching condition is used for processing.

A second object of the invention is to provide a wafer processing apparatus and a wafer processing method with reduced within-wafer dimensional variation in which, even in etching performed in a plurality of steps, an optimal wafer temperature distribution is selected for each step.

The foregoing first object is achieved by a wafer processing apparatus in which the temperature of the semiconductor wafer can be regulated by regulating the temperature by circulating temperature regulating agent in at least two separate circuits of pipings for circulating temperature regulating agent provided in the wafer stage, the temperature of the temperature regulating agent being separately regulated for each circuit of piping; or regulating a heat transfer coefficient between the semiconductor wafer and the wafer stage by regulating cooling gas pressure for each of a plurality of cooling gas feeding circuits provided for feeding cooling gas between the semiconductor wafer and the wafer stage; or regulating input power for each heater of at least one or more circuits of heaters provided in the wafer stage. A control computer coupled to the wafer processing apparatus is operable to receive input of CD measurements for processes in an arbitrary plurality of temperature conditions, to determine a relationship equation between the temperature and the CD value and find a temperature condition for obtaining an arbitrary within-wafer CD distribution from the relationship equation, and to perform processing in the condition.

The foregoing second object is achieved by a wafer processing apparatus in which the temperature of the semiconductor wafer can be regulated by regulating the temperature by circulating temperature regulating agent in at least two separate circuits of pipings for circulating temperature regulating agent provided in the wafer stage, the temperature of the temperature regulating agent being separately regulated for each circuit of piping; or regulating a heat transfer coefficient between the wafer and the wafer stage by regulating cooling gas pressure for each of a plurality of cooling gas feeding circuits provided for feeding cooling gas between the semiconductor wafer and the wafer stage; or regulating input power for each heater of at least one or more circuits of heaters provided in the wafer stage. A control computer coupled to the wafer processing apparatus is operable to receive input of CD measurements for processes in an arbitrary plurality of temperature conditions for each step, to determine a relationship equation between the temperature and the CD value for each step and find a temperature condition for obtaining an arbitrary within-wafer CD distribution for each step from the relationship equation, and to perform processing in the condition for each step.

According to the invention, the temperature condition for obtaining a uniform CD distribution within a wafer can be uniquely determined, and this temperature condition can be used for plasma processing. A process condition can thus be established in a short period of time. As a result, the invention can provide a wafer processing apparatus and a wafer processing method that achieve a uniform CD distribution within a wafer.

Furthermore, according to the invention, in sequential processing for different kinds of films, each kind of film can be processed in a particular temperature condition for obtaining a uniform CD distribution within a wafer. As a result, the invention can provide a wafer processing apparatus and a wafer processing method that achieve a uniform CD distribution within a wafer.

### BRIEF DESCRIPTION OF THE DRAWINGS

FIG. 1 is a schematic cross section of a wafer stage of a first embodiment of the invention.

FIG. 2 is a schematic cross section of a plasma processing apparatus of the first embodiment of the invention.

FIG. 3 illustrates the CD shift in etching polysilicon with a hard mask.

FIG. 4 shows a flow chart for determining the etching condition of the first embodiment of the invention.

FIG. 5 shows a within-wafer distribution of CD shift before and after etching in which the invention is not practiced.

FIG. 6 shows a result of actual measurement and simulation on the wafer temperature during processing.

FIG. 7 shows the relationship between temperature and CD.

FIG. 8 shows a temperature distribution for a radially uniform CD shift.

FIG. 9 shows a within-wafer distribution of CD shift before and after etching in which the invention is practiced.

FIG. 10 illustrates the CD shift in sequentially etching antireflective coating (BARC) and polysilicon with a resist mask.

FIG. 11 shows a flow chart for determining the etching condition of a second embodiment of the invention.

FIG. 12 shows a flow chart for determining the etching condition of a third embodiment of the invention.

FIG. 13 shows a flow chart of a fourth embodiment of the invention.

### DETAILED DESCRIPTION OF THE PREFERRED EMBODIMENTS

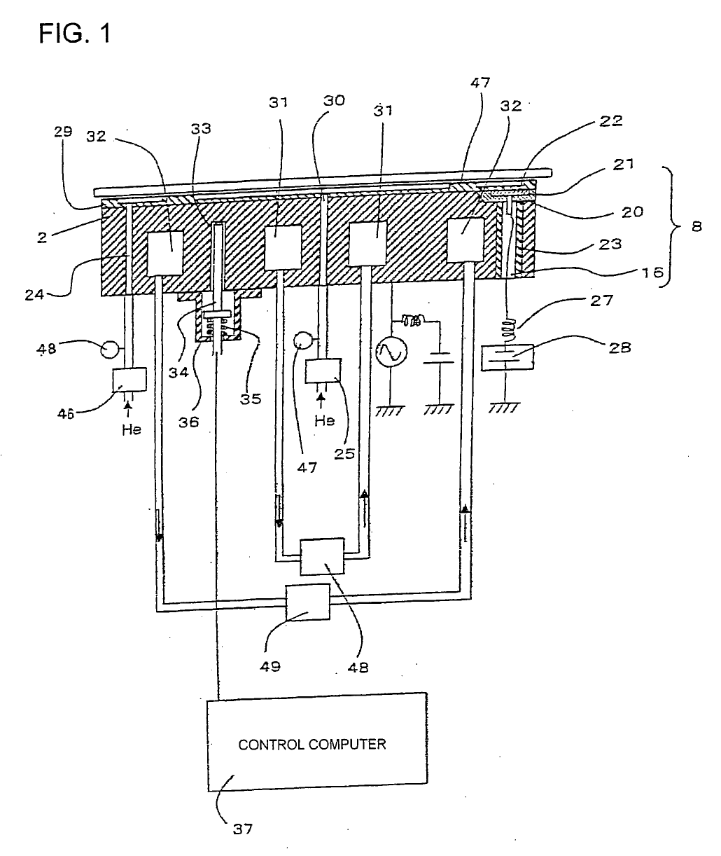

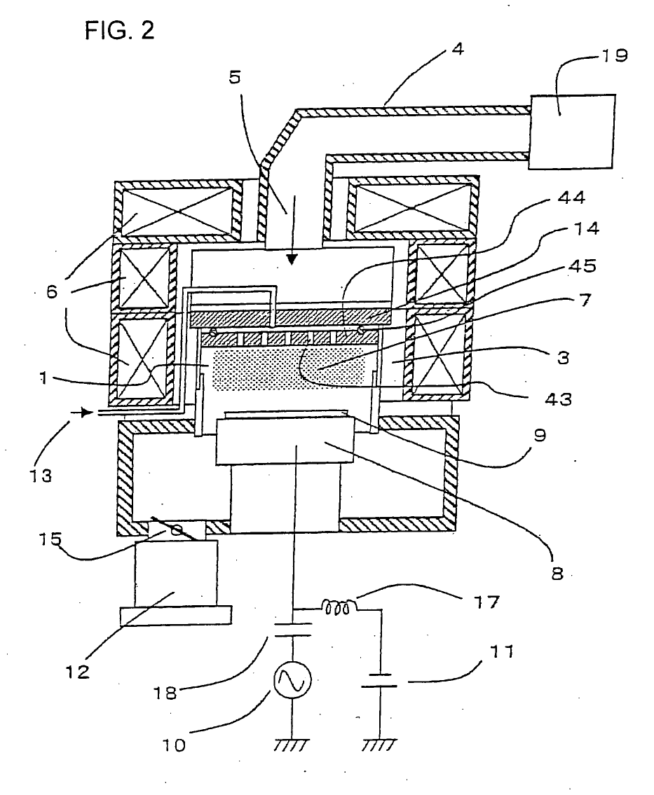

FIGS. 1 and 2 show an example in which a first embodiment of the invention is applied to a magneto-microwave plasma processing apparatus (wafer processing apparatus). FIG. 2 is a schematic cross section of a plasma processing apparatus according to the first embodiment of the invention. FIG. 1 is a schematic cross section of a wafer stage of the first embodiment of the invention. First, a magneto-microwave plasma processing apparatus is briefly described with reference to FIG. 2.

A quartz window 14 is provided on top of a vacuum chamber 3. A wafer 9 is fixed on a wafer stage 8 in a vacuum process chamber 1. The wafer stage 8 has a capability of electrostatic chuck, which will be described later in detail. Below the quartz window 14, via an O-ring 45, is installed a shower plate 44 having gas holes 43 for feeding process gas into the process chamber. Process gas 13 supplied between the quartz window and the shower plate is fed into the process chamber through the gas holes. The process gas is in a plasma state 7 by the interaction between microwaves 5 generated by a microwave oscillator 19 and fed through a waveguide 4, and a magnetic field generated by coils 6 placed around the vacuum chamber 3. The semiconductor wafer is processed (in this example, etched) by being exposed to this plasma. In particular, a RF power supply 10 connected via a capacitor 18 controls the etching condition by controlling injection of ions. A DC power supply 11 applies voltage to the electrostatic chuck unit. Coil 17 is a coil for preventing in flow of RF components. Vacuum pump 12 keeps the pressure in the process chamber at a constant level by regulating the degree of opening of a valve 15.

Referring now to FIG. 1, the configuration of the wafer stage 8 of this embodiment is described in detail. The matrix 2 of the wafer stage 8 is made of aluminum. A step 20 is provided on the upper face of the periphery of the matrix. The step is sprayed with high-resistance alumina 21 for the purpose of electrically insulating the matrix. The surface of the high-resistance alumina is sprayed with a heater 22 of tungsten. The heater is fed via a through hole 16 provided in the high-resistance alumina film and the matrix. In this embodiment, the matrix 2 is provided with the through hole 16, in which a ceramics pipe 23 for electric insulation is embedded. The heater is connected to a heater power supply 28 via a coil 27 served as a filter for preventing inflow of RF voltage. The output of the heater power supply 28 is controlled by a control computer 37. While only a single feeding point for the heater is shown in FIG. 1, it is understood that two feeding points are required in practice. In addition, while the heater power supply 28 in this embodiment is a DC power supply, it is not necessary and can be an AC power supply. The surface of the high-resistance alumina and the heater is sprayed with a ceramics film 29 served as an electrostatic chuck film. As a result, application of DC voltage to the matrix causes a potential difference between the matrix and the semiconductor wafer. In the generated plasma, the ceramics film is then charged with electric charges and the semiconductor wafer can be fixed by the Coulomb force. In this configuration, the temperature near the periphery of the matrix can be regulated by regulating the electric power inputted to the heater. Therefore, the temperature distribution of the semiconductor wafer, particularly the temperature distribution near the periphery, can be regulated. In addition, while a single-circuit heater is used in this embodiment, a multi-circuit heater could regulate the temperature distribution of the wafer more precisely.

In practice, the semiconductor wafer is etched by being subjected to a bias voltage to attract ions in plasma, which involves heat input in the semiconductor wafer. The increase of wafer temperature associated with this heat input significantly affects etching features. For this reason, the semiconductor wafer must be cooled. However, since the pressure in the process chamber is reduced to about a few pascals, simply mounting the wafer results in insufficient heat transfer. The heat transfer is typically ensured by feeding cooling gas such as helium between the semiconductor wafer and the wafer stage. The heat transfer coefficient depends on the pressure of the fed cooling gas. For the purpose of imparting a radial temperature distribution to the semiconductor wafer for reasons described later, this embodiment includes a cooling gas feed system capable of separately controlling the pressure at the center and at the periphery of the semiconductor wafer. More specifically, a single through hole 30 is located at the center of the wafer stage, and eight through holes 24 are evenly located around its periphery. Each through hole is separately fed with helium gas by a flow rate controller 25, 46 and a manometer 47, 48 for helium gas. In this embodiment, the surface of the wafer stage is provided with a sealing chuck 47 served as a seal to facilitate separate control of the helium pressure near the periphery and at a more internal position along the radius. Flow rate of the flow rate controllers 25, 46 is controlled according to an algorithm preprogrammed in the control computer using signals retrieved from the manometers 47, 48 to the control computer 37.

Heat input from plasma is eventually removed by coolant circulating in the matrix. In this embodiment, for the purpose of imparting a radial temperature distribution to the semiconductor wafer, coolants with different temperatures are circulated in coolant channels 31 and 32. To this end, circulators 48 and 49 are separately connected to the coolant channel 31 located near the center and to the coolant channel 32 located near the periphery, respectively. A radial temperature distribution can be imparted to the matrix by changing preset temperatures for these circulators. Although not practiced in this embodiment, a more distinct temperature difference can be imparted by providing, for example, interspace between the coolant channels 31 and 32 around. The preset temperatures of coolants for the circulators 48, 49 are controlled by the control computer 37.

According to the above configuration, a radial temperature distribution can be imparted to the matrix by the temperature setting of the circulators. Moreover, a radial distribution can be imparted to the heat transfer coefficient between the semiconductor wafer and the wafer stage. Furthermore, the radial temperature distribution within a wafer can be flexibly changed because the amount of heat input to the matrix periphery can be regulated by regulating power inputted to the heater.

The wafer temperature during processing can be directly measured, for example, using a fluorescence thermometer on the rear face of the semiconductor wafer. In this embodiment, however, measurements are made on the temperature of the matrix, which has already been proved to be correlated with the wafer temperature distribution. More specifically, the matrix is provided with a hollow 33, where a sheath thermocouple 34 is fixed to the lower face of the matrix with a spring 35 and a fixing jig 36. In general, the result of measurement with a sheath thermocouple is significantly affected by the contact condition at its tip. However, measurements in this embodiment are reliable because the contact at the tip is always subjected to a constant pressing load by the spring. The temperature measurements are sent to the control computer 37.

As described above, the heater output, the pressure of helium gas, and the preset temperature of the circulators are controlled by the control computer. The following describes how, and for what purpose, the heater output, the pressure of helium gas, and the required preset temperature of the circulators are specifically determined.

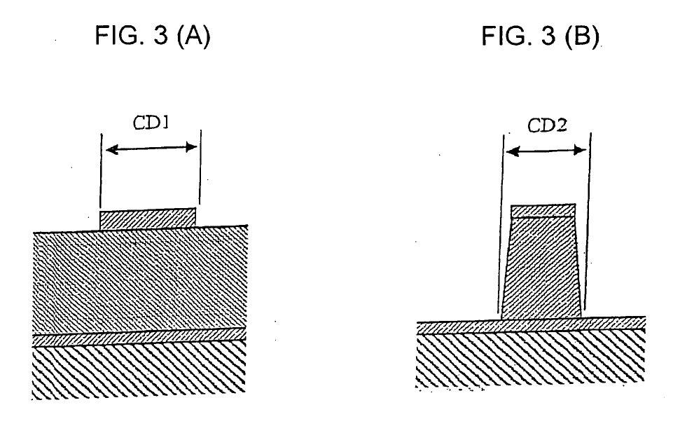

Typically, when a patterned wafer is etched, its CD after processing is smaller than before processing. This variation of line width is referred to as the CD shift. Reference is now made to FIG. 3. FIG. 3A shows a surface of polysilicon patterned with a hard mask before processing. The line width here is denoted by CD1. FIG. 3B shows the situation after etching. The line width here is denoted by CD2. The CD shift is then given by CD2-CD1. In this embodiment, the value of CD2 is smaller than CD1, so that the CD shift assumes a negative value. A smaller value of CD shift means a smaller CD due to processing.

Non-uniform CD shift within a wafer is a problem in the etching process. Within-wafer distribution of the CD shift primarily depends on the following three factors: the plasma distribution above the semiconductor wafer, the density distribution of reaction products on the semiconductor wafer, and the temperature distribution of the semiconductor wafer. Apparatus parameters affecting the respective distributions include source power, distance between electrodes, magnetic field, and pressure for the plasma distribution; gas species, flow rate, pressure, structure of gas feeding unit, source power, and bias power for the density distribution of reaction products; and coolant temperature, cooling gas pressure, heater power, and bias power for the wafer temperature distribution. Of the three factors of plasma distribution, reaction product distribution, and temperature distribution, in particular, the temperature distribution significantly affects the CD shift, and is easy to regulate as an apparatus parameter. Thus the temperature distribution is easy to use as a regulating parameter for the CD distribution within a wafer. For this reason, an object of the embodiment of the invention is to provide a uniform CD distribution within a wafer by optimizing the wafer temperature distribution.

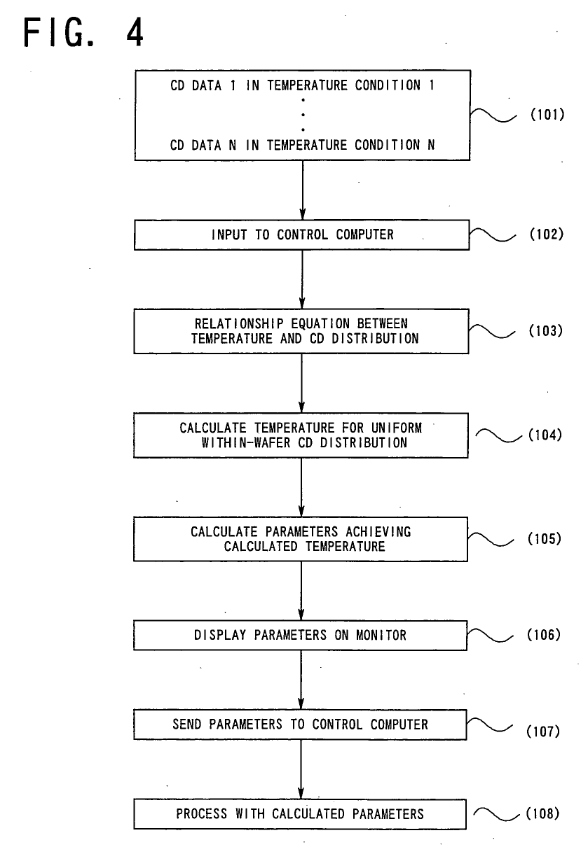

With reference to the flow chart of FIG. 4, a process flow for determining the etching condition is described, which is a feature of the first embodiment of the invention. First, the etching process is performed N times in different temperature conditions of the semiconductor wafer, and the CD shift for each etching iteration is measured (101). Here, in order to reveal the relationship between the wafer temperature and the CD shift, it is desirable that process conditions other than temperature such as gas species, flow rate, pressure, source power, and bias power be identical. These conditions can be determined on the basis of past experiences and results. However, they may be different from the final conditions. If so, the same procedure will be carried out in the modified conditions.

The CD shift data obtained from this experiment is inputted to the control computer (102). The control computer determines a relationship equation between the CD shift and the wafer temperature (103). The wafer temperature can be obtained by actual measurement, simulation, or reference to temperature data stored in the control computer. In the case of simulation, a temperature calculation program prepared beforehand in the control computer is used for the calculation. Next, the control computer calculates a temperature distribution that provides a uniform CD shift within a wafer from the relationship equation between the wafer temperature and the CD shift (104). The control computer then calculates parameters including the preset temperature of coolant, helium pressure, and heater power that achieve this temperature distribution (105). Next, the calculated parameters are displayed on a monitor (106). The parameters are then sent to the control computer (107). The control computer controls the temperature based on the calculated parameters to perform plasma processing (108). Here, the parameters may not be displayed on the monitor unless necessary.

In this embodiment, all the three parameters of coolant temperature, cooling gas pressure, and heater power are used as apparatus parameters for regulating the temperature distribution. However, it is not necessary to use all of them. Instead, one of the three, or a combination of two of the three may be used.

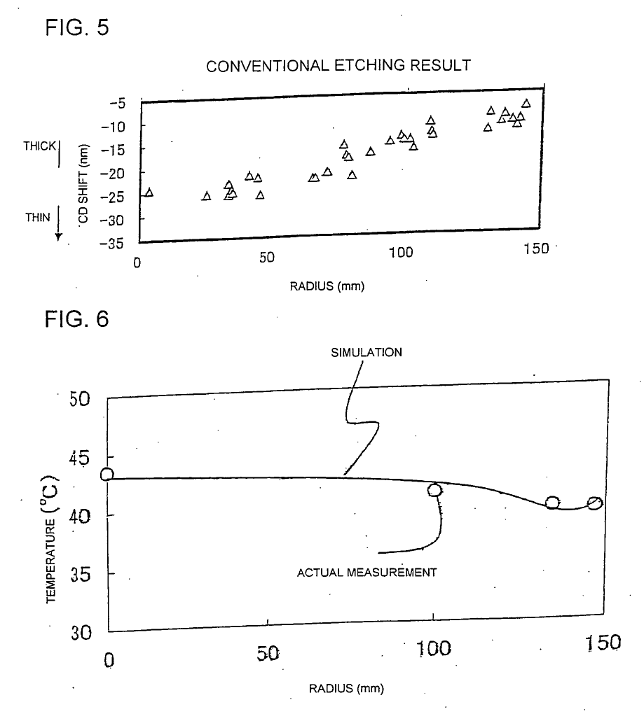

Next, the effect of this embodiment is described. FIG. 5 shows a distribution of CD shift within a wafer obtained when etching is performed without practicing the invention. In this condition, the temperature at the wafer periphery is too low. As a result, since the deposition rate of reaction products is too high near the periphery, the CD shift is small near the wafer periphery. That is, CD tends to be larger near the periphery than near the center.

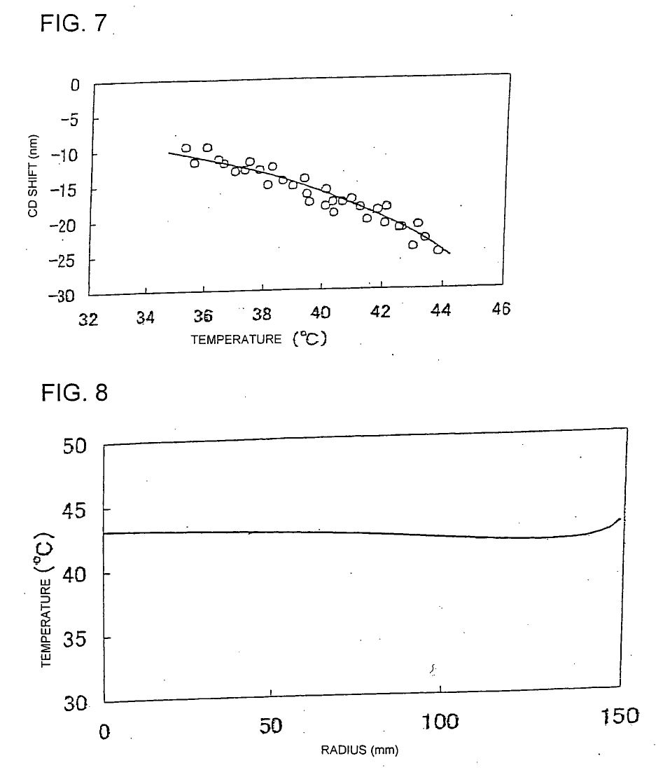

FIG. 6 shows a result of actual measurement and simulation on the wafer temperature during this process. The wafer temperature is measured by using a commercially available semiconductor wafer with a built-in fluorescence thermometer. While this example shows both of actual measurement and simulation, one of them may be used in practice, or temperature information stored beforehand in the control computer may be referred to as described above. FIG. 7 shows the relationship between temperature and CD determined from FIGS. 5 and 6. It is found from this result that the CD shift can be expressed as the following equation (1). In this embodiment, equation (1) was specifically represented by a quadratic function of temperature T.
CD shift=f(T) (1)

Conversely, from equation (1), a temperature distribution for providing a radially uniform CD shift in FIG. 5 can be determined. FIG. 8 shows this temperature distribution. It was found to be preferable that the temperature of coolant circulated in the coolant channel around the periphery be set 6° C. higher.

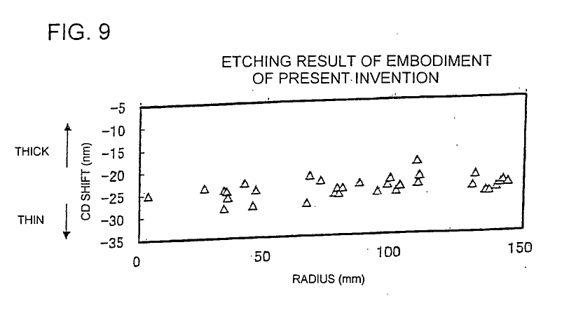

FIG. 9 shows a CD shift distribution obtained when the invention is applied to etch a semiconductor wafer. As shown, when the semiconductor was etched by setting the temperature of its periphery to a higher value according to this embodiment, the deposition rate of reaction products at the periphery was decreased, which resulted in a small CD near the periphery and, in turn, a uniform within-wafer distribution.

In this embodiment, the CD shift is calculated on the assumption that the within-wafer distribution of reaction products remains unchanged in various temperature conditions. In practice, the distribution of reaction products may be changed. In this case, the CD shift is not a function of temperature alone, but a function for which the distribution of reaction products is taken into consideration. For example, it is given by the following equation (2):
CD shift=f(T, RP(r)) (2)
where RP(r) is the density of reaction products at radius r.

In this way, according to this embodiment, the temperature condition for obtaining a uniform CD distribution within a wafer can be uniquely determined, and this temperature condition can be used for plasma processing. A process condition can thus be established in a short period of time. As a result, the invention can provide a wafer processing apparatus that achieves a uniform CD distribution within a wafer.

Moreover, according to this embodiment, even when the etching condition including gas species and pressure is changed as a result of change of an etched object or other reasons, and thereby the CD shift associated with the etching process is changed, the temperature condition for obtaining a uniform CD distribution can be uniquely determined by calculation based on a few CD data for processes in different temperature conditions. Therefore, the invention can provide a plasma processing apparatus having a very short process development time.

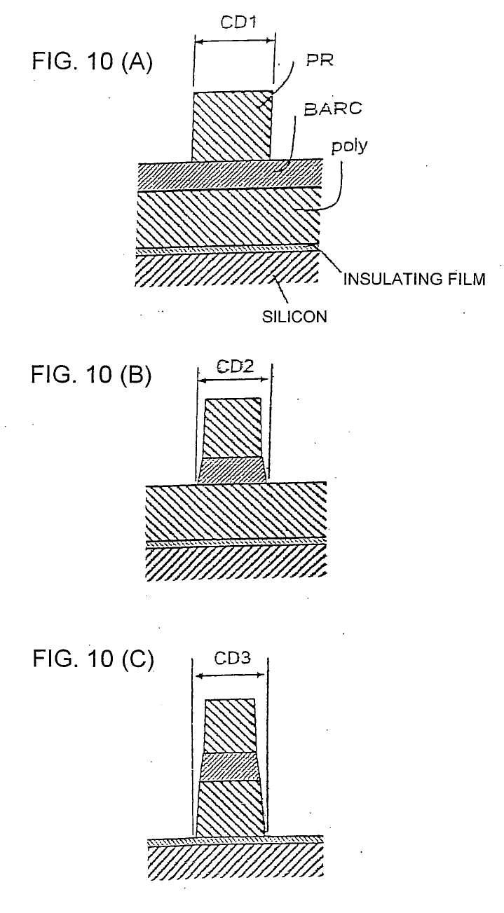

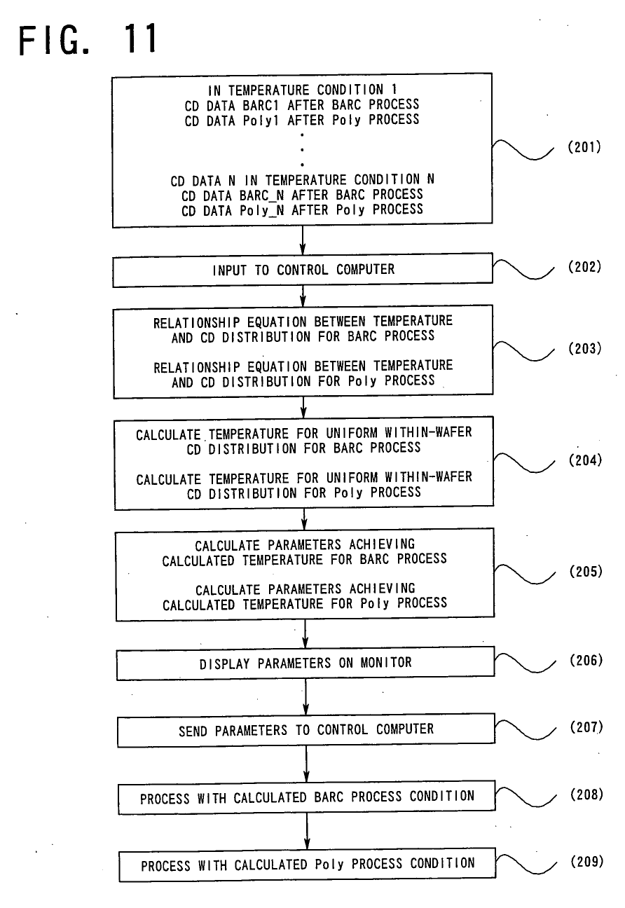

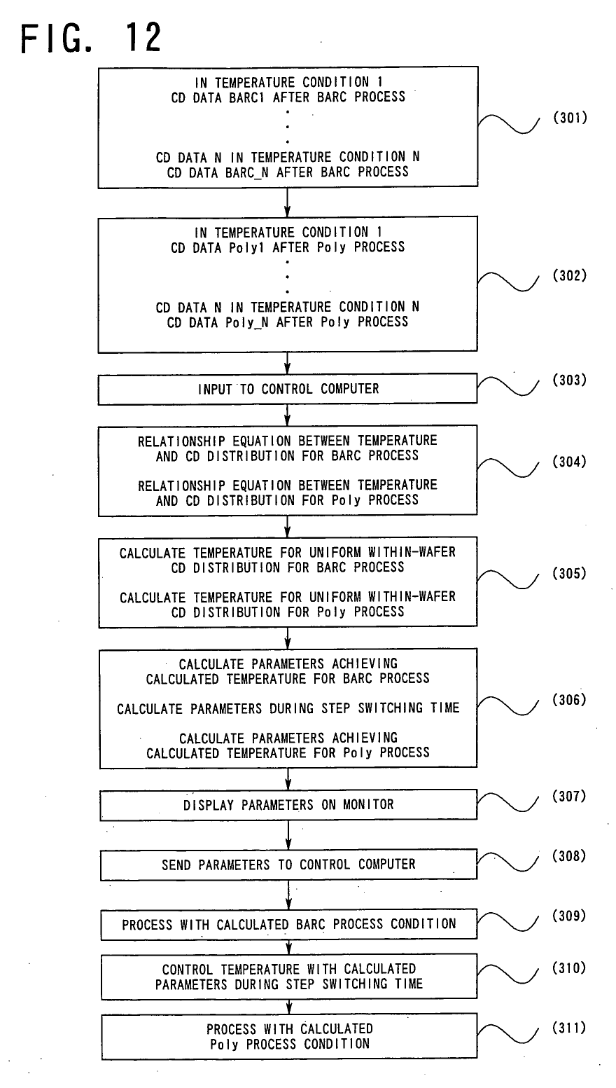

The first embodiment has been described with reference to an example of using a hard mask to etch polysilicon. However, the invention is also effective in sequentially processing a plurality of kinds of films. In this context, the second embodiment of the invention will now be described with reference to FIGS. 10 and 11.

This embodiment is an example of using a resist mask (PR) to sequentially process antireflective coating (BARC) and polysilicon (poly). In this embodiment, BARC is etched by mixed gas of chlorine and oxygen, and polysilicon is etched by mixed gas of chlorine, oxygen, and hydrogen bromide.

As described above, different gas species are used for BARC and polysilicon, which leads to different deposition rates of reaction products for the density distribution and temperature thereof. As a result, the CD distribution for each film after etching is different. In the example of FIG. 10A, CD has a value of CD1 before etching. After BARC etching, CD has a value of CD2 (FIG. 10B). Subsequently, when polysilicon is etched, CD has a value of CD3 (FIG. 10C). While the total CD shift is CD3-CD1, the value CD3 for polysilicon, which is ultimately important, is also affected by CD2. Therefore, regulation of the temperature distribution with attention only to CD3 would produce a result different from a target CD distribution because the value of CD2 may also be changed. Hence the temperature distribution must be regulated for each etching step of BARC etching and polysilicon etching.

In this regard, according to the second embodiment, the flow chart shown in FIG. 11 is used to determine the etching condition for processing. The concept of this embodiment is essentially the same as that of the first embodiment, except that the CD shift is separately controlled before and after BARC etching, and before and after polysilicon etching.

First, only BARC etching is performed a plurality of times in different temperature conditions, and the CD shift for each etching iteration is measured. Here, in order to reveal the relationship between the temperature and the CD shift, it is desirable that process conditions other than temperature such as gas species, flow rate, pressure, source power, and bias power be identical. The end point of BARC etching can be determined by, for example, monitoring plasma emission, monitoring the variation of RF bias voltage, or otherwise. Similarly, data of the CD shift for polysilicon etching is also collected (201). The CD shift data obtained from these experiments is inputted to the control computer (202). Next, the control computer uses the data of the CD shift and the wafer temperature to determine a relationship equation between the temperature and the CD shift for BARC etching and polysilicon etching, respectively (203). The wafer temperature can be obtained by actual measurement, simulation, or reference to temperature data stored in the control computer. In the case of simulation, as with the first embodiment, a temperature calculation program prepared beforehand in the control computer is used for the calculation.

Next, the control computer calculates a temperature distribution that provides a uniform CD shift within a wafer from the relationship equation between the temperature and the CD shift separately for BARC etching and polysilicon etching (204). The control computer then calculates the preset temperature of coolant, helium pressure, and heater power that achieve this temperature distribution separately for BARC etching and polysilicon etching (205). Next, the calculated parameters are displayed on a monitor (206). The parameters are then sent to the control computer (207). The control computer controls the temperature based on the parameters to etch BARC (208). Subsequently, the control computer etches polysilicon (209). Here, the parameters may not be displayed on the monitor unless necessary.

In this embodiment, all the three parameters of coolant temperature, cooling gas pressure, and heater power are used as apparatus parameters for regulating the temperature distribution. However, it is not necessary to use all of them. Instead, one of the three, or a combination of two of the three may be used.

In this way, according to this embodiment, when different kinds of films are sequentially processed, the temperature condition for obtaining a uniform CD distribution within a wafer can be used for processing each kind of film. As a result, the invention can provide a wafer processing apparatus that achieves a uniform CD distribution within a wafer.

Moreover, as with the first embodiment, even when the etching condition including gas-species and pressure is changed, the temperature condition for obtaining a uniform CD distribution can be easily found by measuring CD data in various temperature conditions for each kind of film and inputting the data to the control computer. Therefore, the invention can provide a plasma processing apparatus having a very short process development time.

This embodiment has been described with reference to a case of sequentially processing BARC etching and polysilicon etching. However, the invention is not limited to this combination, but is applicable to sequential processing of other kinds of films based on the same concept.

The second embodiment of the invention is useful because the temperature for each step is regulated to a temperature that provides a uniform within-wafer CD distribution. However, the temperature control may be insufficient for processes of interest that are very sensitive to temperature. For example, the wafer is not at a temperature that provides a uniform within-wafer CD distribution after the step is switched and until the temperature distribution reaches the optimal distribution. Therefore, during this period of time, the CD distribution may be varied. Moreover, if the switched step requires complete replacement of process gas, which lasts several tens of seconds, the temperature of the wafer heated in the preceding step will gradually decrease. This will extend, in the next step, the time required for reaching the optimal wafer temperature that provides a uniform within-wafer CD distribution.

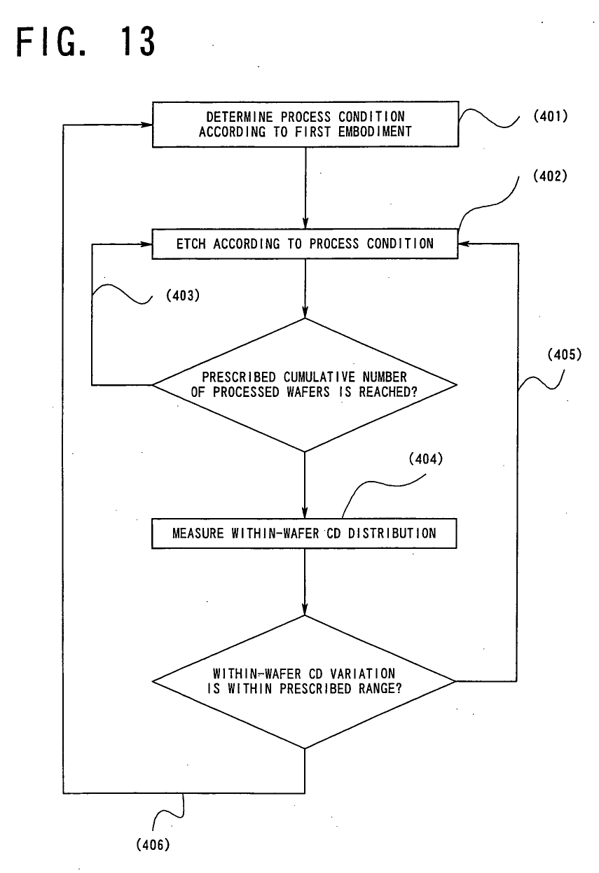

In this regard, the third embodiment of the invention to solve the above problem will be described with reference to FIG. 12. This embodiment is different from the second embodiment essentially in that the wafer temperature between the steps is controlled to be a temperature that provides a uniform within-wafer CD distribution. More specifically, first, only BARC etching is performed a plurality of times in different temperature conditions, and the CD shift for each etching iteration is measured (301). Here, in order to reveal the relationship between the temperature and the CD shift, it is desirable that process conditions other than temperature such as gas species, flow rate, pressure, source power, and bias power be identical. The end point of BARC etching can be determined by, for example, monitoring plasma emission, monitoring the variation of RF bias voltage, or otherwise. Similarly, data of the CD shift for polysilicon etching is also collected (302). Each set of CD shift data obtained from these experiments is inputted to the control computer (303). Next, the control computer uses the data of the CD shift and the wafer temperature to determine a relationship equation between the temperature and the CD shift for BARC etching and polysilicon etching, respectively (304). The wafer temperature can be obtained by actual measurement, simulation, or reference to temperature data stored in the control computer. In the case of simulation, as with the first embodiment, a temperature calculation program prepared beforehand in the control computer is used for the calculation.

Next, the control computer calculates a temperature distribution that provides a uniform CD shift within a wafer from the relationship equation between the wafer temperature and the CD shift separately for BARC etching and polysilicon etching (305). The control computer then calculates the preset temperature of coolant, helium pressure, and heater power that achieve this temperature distribution separately for BARC etching and polysilicon etching (306). The control computer also calculates parameters for regulating the wafer temperature to a temperature that provides a uniform within-wafer CD distribution for polysilicon during the switching time from BARC etching to polysilicon etching (306). Next, the calculated parameters are displayed on a monitor (307). The parameters are then sent to the control computer (308). The control computer controls the temperature based on the parameters to etch BARC (309). The control computer controls the wafer at a temperature that provides a uniform within-wafer CD distribution for polysilicon etching until the subsequent etching is started (310). Subsequently, the control computer etches polysilicon (311). Here, the parameters may not be displayed on the monitor unless necessary.

In this way, according to this embodiment, the wafer temperature can also be controlled during the period including the waiting time between the steps. Therefore, the invention can provide a uniform within-wafer CD distribution with higher precision as compared to the second embodiment.

The foregoing embodiments have been described with reference to an example of the so-called monopole system in which the electrostatic chuck unit of the wafer stage is configured to have a single electrode. However, it is not necessary. Similar advantages can also be expected in the dipole system having a plurality of electrodes. In this case, a wafer can be chucked and detached irrespective of the presence of plasma, which can eliminate the sequence required in the monopole system, and thus improve the throughput.

Next, with reference to FIG. 13, the fourth embodiment is described, which is directed to a processing method that can further improve manufacturing yield when the embodiment of the invention is applied to an actual semiconductor production line. This embodiment is effective in the case where increase of processed wafers in an actual production line results in deposits of reaction products adhered to the inner wall of the vacuum chamber, for example, and reaction products are supplied from the deposits. That is, when the within-wafer CD distribution obtained for the process condition determined from measurements of the original CD distribution is gradually changed by reaction products supplied from the wall, the within-wafer CD distribution is measured each time a predetermined cumulative number of wafers are processed. The process condition is determined again on the basis of this result.

First, the process condition is determined-according to the first embodiment (401). The etching process is performed according to the process condition (402). The process is performed according to the process condition until a predefined cumulative number of wafers is reached (403). When the predefined cumulative number of wafers is reached, the within-wafer CD distribution is measured (404). If the within-wafer CD variation is within a prescribed range, the etching process is performed according to the original process condition (405). If the within-wafer CD variation is out of the prescribed range, the process condition is determined again according to the first embodiment (406).

According to this embodiment, when sequential processing of a large number of wafers results in contamination of the inner wall of the chamber by deposits, from which reaction products are supplied to change the reaction product distribution in the chamber, the process is performed with reviewing the process condition so that a certain range of deviation is preserved. Therefore, the invention can provide a processing method with very high yield.

In this embodiment, the etching condition is reviewed on the basis of the resulting CD distribution. In practice, however, a wet cleaning process and/or a plasma cleaning process may be introduced before reviewing the etching condition. Introduction of these processes may also lead to additional effects such as reducing the possibility of contamination by foreign particles.

What is claimed is:

1. A wafer processing apparatus that regulates temperature of a semiconductor wafer and etches the semiconductor wafer with plasma, the temperature being regulated by at least one of temperature regulating functions of: circulating temperature regulating agent by a temperature regulating agent circulating unit provided in a wafer stage; regulating cooling gas pressure between the semiconductor wafer and the wafer stage; and regulating input power of a heater provided in the wafer stage, wherein
when a temperature distribution within the wafer is specified so that a line width (CD) distribution within the wafer can be arbitrarily specified, a relationship equation between the line width and the temperature is determined from data of the line width and the temperature, the temperature distribution of the wafer is specified from the relationship equation, and the one of the temperature regulating functions is operated to achieve the specified wafer temperature distribution.

2. A wafer processing apparatus that regulates temperature of a semiconductor wafer and etches the semiconductor wafer with plasma, the temperature being regulated by at least one of temperature regulating functions of: circulating temperature regulating agent by a temperature regulating agent circulating unit provided in a wafer stage; regulating cooling gas pressure between the semiconductor wafer and the wafer stage; and regulating input power of a heater provided in the wafer stage, wherein
in sequentially processing a plurality of kinds of films, when a temperature distribution within the wafer is specified so that a line width (CD) distribution of each film within the wafer can be arbitrarily specified, a relationship equation between the line width and the temperature of each film is determined from data of the line width and the temperature of each film measured for each wafer, the temperature distribution of the wafer for each film is specified from the relationship equation, and the one of the temperature regulating functions is operated to achieve the specified wafer temperature distribution.

3. A wafer processing apparatus that regulates temperature of a semiconductor wafer and etches the semiconductor wafer with plasma, the temperature being regulated by at least one of temperature regulating functions of: circulating temperature regulating agent by a temperature regulating agent circulating unit provided in a wafer stage; regulating cooling gas pressure between the semiconductor wafer and the wafer stage; and regulating input power of a heater provided in the wafer stage, wherein
in sequentially processing a plurality of kinds of films, when a temperature distribution within the wafer is specified so that a line width (CD) distribution of each film within the wafer can be arbitrarily specified, a relationship equation between the line width and the temperature of each film is determined from data of the line width and the temperature measured for each film for each wafer, the temperature distribution of the wafer for each film is specified from the relationship equation, and the one of the temperature regulating functions is operated to achieve the specified wafer temperature distribution.

4. A wafer processing apparatus according to claim 1, wherein
a control computer coupled to the wafer processing apparatus can receive input of line width dimensions resulting from processes in an arbitrary plurality of temperature conditions obtained by changing one of the conditions of the temperature of the temperature regulating agent, the cooling gas pressure, and the input power of the heater; the line width dimensions are used to calculate at least one of the temperature of the temperature regulating agent, the cooling gas pressure, and the input power of the heater for obtaining an arbitrary etching dimension; and the calculation result is used for display or control.

5. A wafer processing apparatus according to claim 2, wherein
a control computer coupled to the wafer processing apparatus can receive input of line width dimensions resulting from processes in an arbitrary plurality of temperature conditions obtained by changing one of the conditions of the temperature of the temperature regulating agent, the cooling gas pressure, and the input power of the heater; the line width dimensions are used to calculate at least one of the temperature of the temperature regulating agent, the cooling gas pressure, and the input power of the heater for obtaining an arbitrary etching dimension; and the calculation result is used for display or control.

6. A wafer processing apparatus according to claim 3, wherein
a control computer coupled to the wafer processing apparatus can receive input of line width dimensions resulting from processes in an arbitrary plurality of temperature conditions obtained by changing one of the conditions of the temperature of the temperature regulating agent, the cooling gas pressure, and the input power of the heater; the line width dimensions are used to calculate at least one of the temperature of the temperature regulating agent, the cooling gas pressure, and the input power of the heater for obtaining an arbitrary etching dimension; and the calculation result is used for display or control.

7. A wafer processing apparatus according to claim 1, wherein
the temperature of the semiconductor wafer can be regulated by at least one of:
regulating the temperature by circulating temperature regulating agent in at least two separate circuits of pipings for circulating temperature regulating agent, the pipings being provided in the wafer stage intended for mounting the semiconductor wafer, the temperature of the temperature regulating agent being separately regulated for each circuit of piping;
regulating a heat transfer coefficient between the semiconductor wafer and the wafer stage by regulating cooling gas pressure for each of a plurality of cooling gas feeding circuits provided for feeding cooling gas between the semiconductor wafer and the wafer stage; and
regulating input power for each heater of at least one or more circuits of heaters provided in the wafer stage; and wherein
a control computer coupled to the wafer processing apparatus can receive input of line width dimensions resulting from processes in an arbitrary plurality of temperature conditions obtained by changing at least one of the conditions of the temperature of the temperature regulating agent and the cooling gas pressure or at least one of the conditions of the temperature of the temperature regulating agent; the cooling gas pressure, and the input power of the heater; the line width dimensions are used to calculate at least one of the temperature of the temperature regulating agent, the cooling gas pressure, and the input power of the heater for obtaining an arbitrary etching line width dimension; and the calculation result is used for display or control.

8. A wafer processing apparatus according to claim 2, wherein
the temperature of the semiconductor wafer can be regulated by at least one of:
regulating the temperature by circulating temperature regulating agent in at least two separate circuits of pipings for circulating temperature regulating agent, the pipings being provided in the wafer stage intended for mounting the semiconductor wafer, the temperature of the temperature regulating agent being separately regulated for each circuit of piping;
regulating a heat transfer coefficient between the semiconductor wafer and the wafer stage by regulating cooling gas pressure for each of a plurality of cooling gas feeding circuits provided for feeding cooling gas between the semiconductor wafer and the wafer stage; and
regulating input power for each heater of at least one or more circuits of heaters provided in the wafer stage; and wherein
a control computer coupled to the wafer processing apparatus can receive input of line width dimensions resulting from processes in an arbitrary plurality of temperature conditions obtained by changing at least one of the conditions of the temperature of the temperature regulating agent and the cooling gas pressure or at least one of the conditions of the temperature of the temperature regulating agent, the cooling gas pressure, and the input power of the heater; the line width dimensions are used to calculate at least one of the temperature of the temperature regulating agent, the cooling gas pressure, and the input power of the heater for obtaining an arbitrary etching line width dimension; and the calculation result is used for display or control.

9. A wafer processing apparatus according to claim 3, wherein
the temperature of the semiconductor wafer can be regulated by at least one of:
regulating the temperature by circulating temperature regulating agent in at least two separate circuits of pipings for circulating temperature regulating agent, the pipings being provided in the wafer stage intended for mounting the semiconductor wafer, the temperature of the temperature regulating agent being separately regulated for each circuit of piping;
regulating a heat transfer coefficient between the semiconductor wafer and the wafer stage by regulating cooling gas pressure for each of a plurality of cooling gas feeding circuits provided for feeding cooling gas between the semiconductor wafer and the wafer stage; and
regulating input power for each heater of at least one or more circuits of heaters provided in the wafer stage; and wherein
a control computer coupled to the wafer processing apparatus can receive input of line width dimensions resulting from processes in an arbitrary plurality of temperature conditions obtained by changing at least one of the conditions of the temperature of the temperature regulating agent and the cooling gas pressure or at least one of the conditions of the temperature of the temperature regulating agent, the cooling gas pressure, and the input power of the heater; the line width dimensions are used to calculate at least one of the temperature of the temperature regulating agent, the cooling gas pressure, and the input power of the heater for obtaining an arbitrary etching line width dimension; and the calculation result is used for display or control.

10. A wafer processing apparatus according to claim 1, wherein
the temperature of the semiconductor wafer can be regulated by at least one of:
regulating the temperature by circulating temperature regulating agent in at least two separate circuits of pipings for circulating temperature regulating agent, the pipings being provided in the wafer stage intended for mounting the semiconductor wafer, the temperature of the temperature regulating agent being separately regulated for each circuit of piping;
regulating a heat transfer coefficient between the semiconductor wafer and the wafer stage by regulating cooling gas pressure for each of a plurality of cooling gas feeding circuits provided for feeding cooling gas between the semiconductor wafer and the wafer stage; and
regulating input power for each heater of at least one or more circuits of heaters provided in the wafer stage; and wherein
under instructions from a control computer coupled to the wafer processing apparatus, a sequence of etching processes composed of a plurality of steps is performed with regulating, for each of the steps, at least one of the temperature of the temperature regulating agent, the cooling gas pressure, and the input power of the heater.

11. A wafer processing apparatus according to claim 2, wherein
the temperature of the semiconductor wafer can be regulated by at least one of:
regulating the temperature by circulating temperature regulating agent in at least two separate circuits of pipings for circulating temperature regulating agent, the pipings being provided in the wafer stage intended for mounting the semiconductor wafer, the temperature of the temperature regulating agent being separately regulated for each circuit of piping;
regulating a heat transfer coefficient between the semiconductor wafer and the wafer stage by regulating cooling gas pressure for each of a plurality of cooling gas feeding circuits provided for feeding cooling gas between the semiconductor wafer and the wafer stage; and
regulating input power for each heater of at least one or more circuits of heaters provided in the wafer stage; and wherein
under instructions from a control computer coupled to the wafer processing apparatus, a sequence of etching processes composed of a plurality of steps is performed with regulating, for each of the steps, at least one of the temperature of the temperature regulating agent, the cooling gas pressure, and the input power of the heater.

12. A wafer processing apparatus according to claim 3, wherein
the temperature of the semiconductor wafer can be regulated by at least one of:
regulating the temperature by circulating temperature regulating agent in at least two separate circuits of pipings for circulating temperature regulating agent, the pipings being provided in the wafer stage intended for mounting the semiconductor wafer, the temperature of the temperature regulating agent being separately regulated for each circuit of piping;
regulating a heat transfer coefficient between the semiconductor wafer and the wafer stage by regulating cooling gas pressure for each of a plurality of cooling gas feeding circuits provided for feeding cooling gas between the semiconductor wafer and the wafer stage; and
regulating input power for each heater of at least one or more circuits of heaters provided in the wafer stage; and wherein
under instructions from a control computer coupled to the wafer processing apparatus, a sequence of etching processes composed of a plurality of steps is performed with regulating, for each of the steps, at least one of the temperature of the temperature regulating agent, the cooling gas pressure, and the input power of the heater.

13. A wafer processing apparatus according to claim 1, wherein
the temperature of the semiconductor wafer can be regulated by at least one of:
regulating the temperature by circulating temperature regulating agent in at least two separate circuits of pipings for circulating temperature regulating agent, the pipings being provided in the wafer stage intended for mounting the semiconductor wafer, the temperature of the temperature regulating agent being separately regulated for each circuit of piping;
regulating a heat transfer coefficient between the semiconductor wafer and the wafer stage by regulating cooling gas pressure for each of a plurality of cooling gas feeding circuits provided for feeding cooling gas between the semiconductor wafer and the wafer stage; and
regulating input power for each heater of at least one or more circuits of heaters provided in the wafer stage; and wherein
during a time period between an arbitrary step and a next step performed subsequent to the arbitrary step in a sequence of etching processes composed of a plurality of steps, at least one function of the temperature regulating functions is used to keep the temperature at a wafer temperature used in the next step.

14. A wafer processing apparatus according to claim 2, wherein
the temperature of the semiconductor wafer can be regulated by at least one of:
regulating the temperature by circulating temperature regulating agent in at least two separate circuits of pipings for circulating temperature regulating agent, the pipings being provided in the wafer stage intended for mounting the semiconductor wafer, the temperature of the temperature regulating agent being separately regulated for each circuit of piping;
regulating a heat transfer coefficient between the semiconductor wafer and the wafer stage by regulating cooling gas pressure for each of a plurality of cooling gas feeding circuits provided for feeding cooling gas between the semiconductor wafer and the wafer stage; and
regulating input power for each heater of at least one or more circuits of heaters provided in the wafer stage; and wherein
during a time period between an arbitrary step and a next step performed subsequent to the arbitrary step in a sequence of etching processes composed of a plurality of steps, at least one function of the temperature regulating functions is used to keep the temperature at a wafer temperature used in the next step.

15. A wafer processing apparatus according to claim 3, wherein
the temperature of the semiconductor wafer can be regulated by at least one of:
regulating the temperature by circulating temperature regulating agent in at least two separate circuits of pipings for circulating temperature regulating agent, the pipings being provided in the wafer stage intended for mounting the semiconductor wafer, the temperature of the temperature regulating agent being separately regulated for each circuit of piping;
regulating a heat transfer coefficient between the semiconductor wafer and the wafer stage by regulating cooling gas pressure for each of a plurality of cooling gas feeding circuits provided for feeding cooling gas between the semiconductor wafer and the wafer stage; and
regulating input power for each heater of at least one or more circuits of heaters provided in the wafer stage; and wherein
during a time period between an arbitrary step and a next step performed subsequent to the arbitrary step in a sequence of etching processes composed of a plurality of steps, at least one function of the temperature regulating functions is used to keep the temperature at a wafer temperature used in the next step.
